(19) United States
(12) Patent Application Publication
(10) Pub. No.: US 2004/0218364 A1
(43) Pub. Date: Nov. 4, 2004

(54) Application specific heatsink assembly

(76) Inventors: Peter J. Martinez, Colorado Springs, CO (US); Arthur Fong, Colorado Springs, CO (US); Marvin Glenn Wong, Woodland Park, CO (US)

Correspondence Address: AGILENT TECHNOLOGIES, INC., Intellectual Property Administration, Legal Department, DL429, P.O. Box 7599, Loveland, CO, 80537-0599, US

(21) Appl. No.: 10/427,295

(22) Filed: Apr. 30, 2003

(51) Int. Cl. H05K 7/20

(52) U.S. Cl. 361/719

(57) ABSTRACT

An application specific heat sink assembly is presented in which a heat-dissipating substrate is selected of a particular size, shape and material in order to meet predetermined heat-dissipating requirements and a heat-dissipating stud is selected or formed of a particular size, shape and material in order to meet predetermined requirements. The heat-dissipating substrate and heat-dissipating stud form a heat sink assembly having application specific features selected to optimize the heat-dissipating, CTE matching, environmental resistance requirements, low mass requirements, size, machinability, cost structure and other desirable features of a particular application for dissipating heat from an electronic component.

### BACKGROUND OF THE INVENTION

Electronic components, such as integrated circuits or printed circuit boards, are becoming more and more common in various devices. For example, central processing units, interface, graphics and memory circuits typically comprise several integrated circuits. During normal operations, many electronic components, such as integrated circuits, generate significant amounts of heat. If the heat generated during the operation of these and other devices is not removed, the electronic components or other devices near them may overheat, resulting in damage to the components or degradation of component performance.

In order to avoid such problems caused by over heating, heat sinks or other heat-dissipating devices are often used with electronic components to dissipate heat. One must balance the heat-dissipating requirements of a heat sink with other factors. Heat sinks may crack, damage or separate from the electronic components they are attached to if the heat sink has a coefficient of thermal expansion significantly different from the electronic component. Also, many heat sink materials are relatively heavy. If the electronic component the heat sink is attached to is subjected to vibration or impact, the weight of the heat sink attached to the electronic component may crack, damage or cause the heat sink to separate from the electronic component to which it is attached.

Some materials provide good thermal conductivity, but are difficult to shape, expensive, heavy or have other less desirable features to a particular heat-dissipating situation.

Accordingly, there exists a need in the industry for the ability to optimize heat dissipation, weight, cost, machinability and other features of a heat-dissipating device.

### SUMMARY OF THE INVENTION

An apparatus and method for optimizing heat dissipation, CTE matching, weight, cost, machinability or other features of a heat dissipation device.

The apparatus comprises an application specific heat sink device for dissipating heat from an electronic component, the application specific heat sink device may have a heat-dissipating substrate selected for one or more of its size, shape, mass, cost, thermal conductivity, or environmental resistance properties; and a heat-dissipating stud selected for its CTE and machinability properties, such that the heat-dissipating stud may be attached to the heat-dissipating substrate such that the electronic component may be attached to the heat-dissipating stud.

A method for manufacturing an application specific heat sink device, which may include selecting or forming a heat-dissipating substrate; forming a heat-dissipating stud, such that the heat-dissipating stud may be shaped and sized to mate with an electronic device to be cooled; and attaching the heat-dissipating stud to the substrate.

### BRIEF DESCRIPTION OF THE DRAWINGS

A more complete appreciation of this invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 illustrates a first embodiment of a heat-dissipating device in accordance with the present invention;

FIG. 2 illustrates a second embodiment of a heat-dissipating device in accordance with the present invention;

FIG. 3 illustrates a third embodiment of a heat-dissipating device in accordance with the present invention;

FIG. 4 illustrates a flow chart for manufacturing a heat-dissipating device in accordance with the first embodiment of the present invention;

FIG. 5 illustrates a flow chart for manufacturing a heat-dissipating device in accordance with the second embodiment of the present invention;

FIG. 6 illustrates a flow chart for manufacturing a heat-dissipating device in accordance with the third embodiment of the present invention;

FIG. 7 illustrates a top plan view of an integrated circuit device package according to a fourth embodiment of the invention prior to encapsulation; and

FIG. 8 illustrates a cross-sectional view of the integrated circuit device of FIG. 7 taken along line 8-8.

### DETAILED DESCRIPTION

As shown in the drawings for purposes of illustration, the present invention relates to techniques for providing a heat-dissipating device in which the various features of the device, e.g. thermal conductivity, precise tolerances, CTE matching with the part to be cooled, environmental resistance, low mass, good bondability, cost, machinability, etc., may be selectively optimized. Optimizing various features of a heat sink device may be accomplished with a heat sink of more than one material, creating an application specific heat sink structure capable of meeting different requirements in different locations more readily than a monolithic heat sink structure.

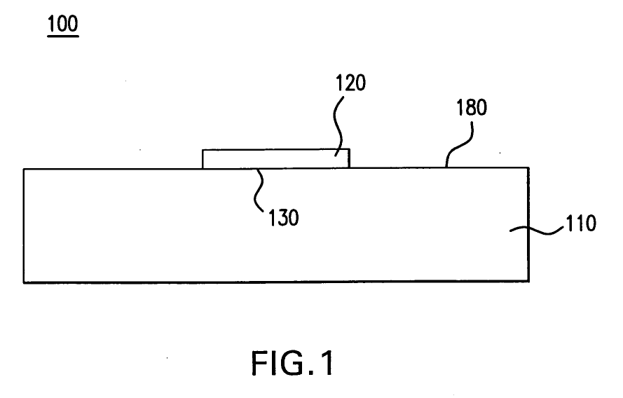

Turning now to the drawings, FIG. 1 illustrates a heat dissipation device according to a first embodiment of the present invention. A heat dissipation substrate 110 is provided. The heat dissipation substrate 110 may be selected from any known heat sink material, alloy or combination thereof, such as Aluminum Silicon Carbide, Copper, Aluminum, carbon/metal composite, ceramic or other known heat sink material. By way of example only, AlSiC may be selected for its heat conducting qualities and low weight. A heat-dissipating stud 120 may be formed by stamping, machining, etching or laser cutting from any known heat sink material, alloy or combination thereof, such as copper, tungsten, molybdenum, aluminum, copper/molybdenum/copper or other known heat sink material.

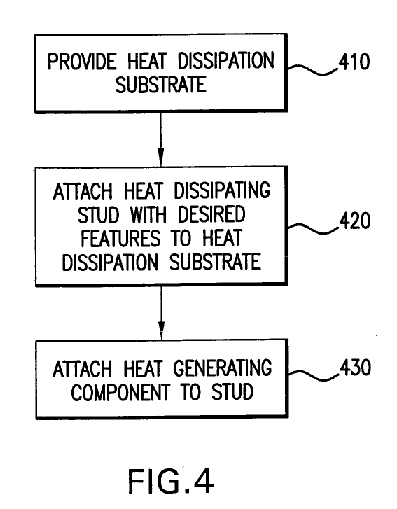

Heat stud 120 may be selected in order to have a CTE (coefficient of thermal expansion) that is relatively close to the device (integrated circuit chip, integrated circuit package, integrated circuit module, printed circuit board, etc.) to which it is to be attached. As shown in the flow chart in FIG. 4, the heat dissipation stud 120 may be attached to the surface 180 of the heat dissipation substrate 110 at a predetermined location 130 by any known means of attachment, such as brazing, soldering, adhesive bonding, press fit, screws, rivets, welding, cold diffusion under high pressure, diffusion bonding, or a thermally conductive metallic adhesive. The heat-dissipating stud 120 is precisely shaped by means of machining, stamping, etching or laser cutting and attached to the heat dissipation substrate 110 at a predetermined location 130.

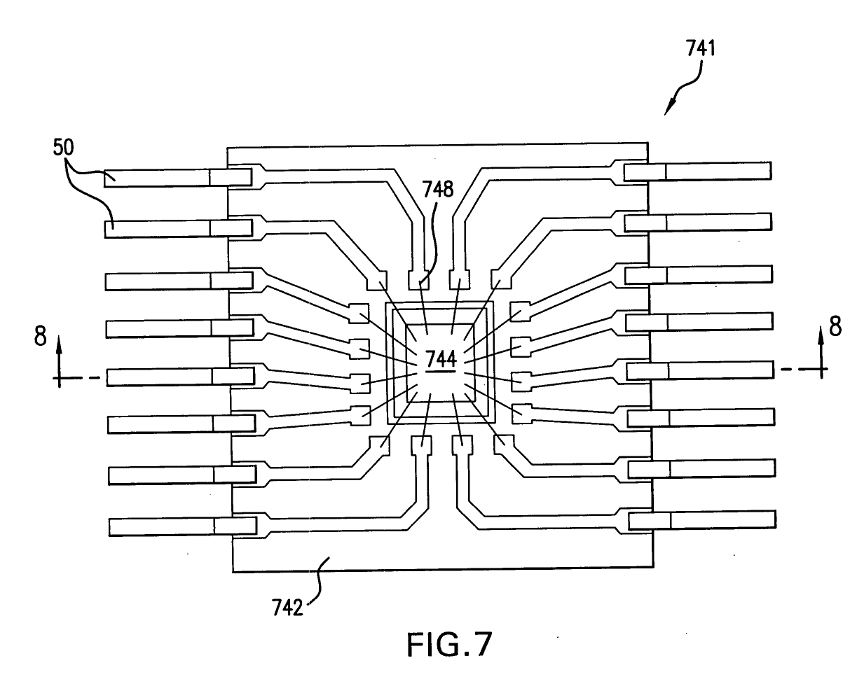

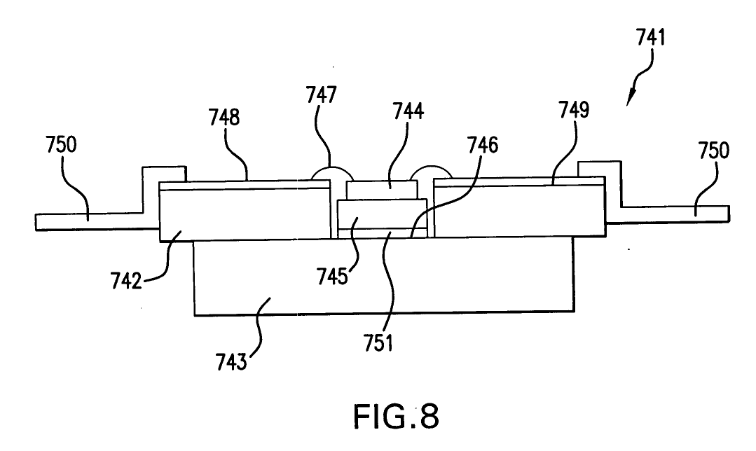

As the application specific heat sink of the present invention is versatile, various heat-dissipating substrates 110 of various materials and sizes may be kept on hand. Various heat-dissipating studs 120 of various materials and sizes may be kept on hand. Thus, the manufacturer of the device to be cooled (one exemplary embodiment shown in FIGS. 7-8) may select the substrate 110 and stud 120 for a particular heat-dissipating application by feature requirements, cost, low mass, good thermal conductivity, precise tolerances, etc. In such a case, as shown in FIG. 4, the manufacturer may select 410 the substrate 110, select the stud 120 and select an appropriate attachment method 420 as required by the particular application in order to optimize the heat sink features to the application, while minimizing heat sink costs. The device to be cooled may be attached to the stud 420. It should be noted, that the stud 120 may be attached to the device to be cooled before the stud 120 is attached to the substrate 110.

Alternatively, the manufacturer may keep various heat-dissipating substrates 110 of varying materials and sizes on hand or order from a supplier. Once the heat-dissipating substrate 110 is selected 410 for a particular application, a customized heat-dissipating stud 120 may be fabricated to specific size, thermal conductivity requirements, etc. After the stud 120 is manufactured, it may be attached 420 by any attachment method appropriate to the application. This embodiment may permit the substrate 110 to be of a material, alloy, or composite that is not readily machinable, but has other desirable heat sink features, such as good thermal conductivity, inexpensive, low mass, etc, while the stud 120 may provide other features, such as improved CTE matching with the device to be cooled, more precise machinability for sizing to match the device to be cooled, etc.

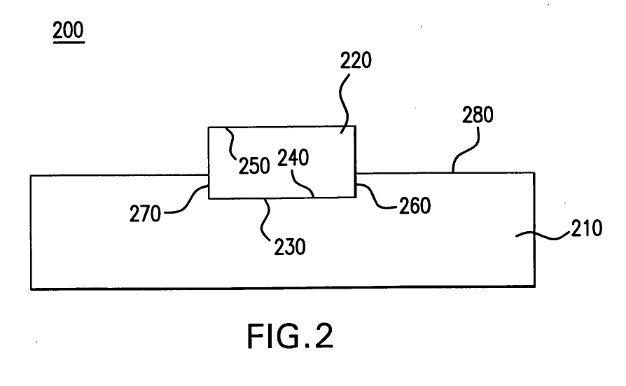

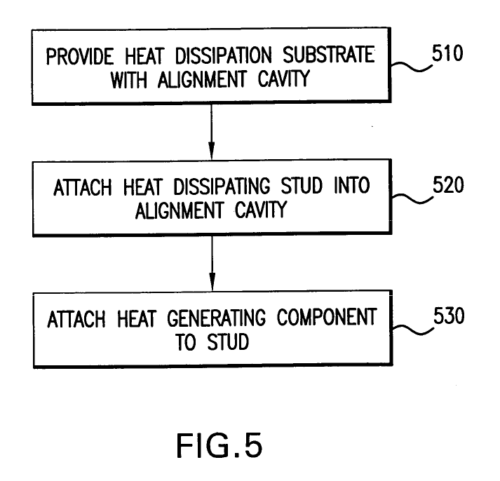

FIG. 2 shows a heat-dissipating device according to a second embodiment of the present invention. In FIG. 2, a heat-dissipating substrate 210 is provided with an alignment cavity 230 for aligning and attaching a heat-dissipating stud 220. The heat-dissipating substrate 210 may be formed by any known method, such as, machining or stamping. The cavity 230 may be formed in substrate 210 by machining or coining/stamping. As shown in the flow chart of FIG. 5, once the substrate is selected 510, the stud 220 may be attached 520 in the alignment cavity 230 by means of brazing, soldering, adhesive bonding, diffusion bonding, cold diffusion under high pressure, a thermally conductive metallic adhesive or other known attachment means. The device to be cooled (not shown) may be attached 530 to the stud 220 by means of any standard die attach method, including epoxy or eutectic die attach. This embodiment may provide for more precise alignment of the stud 220 on the substrate 210.

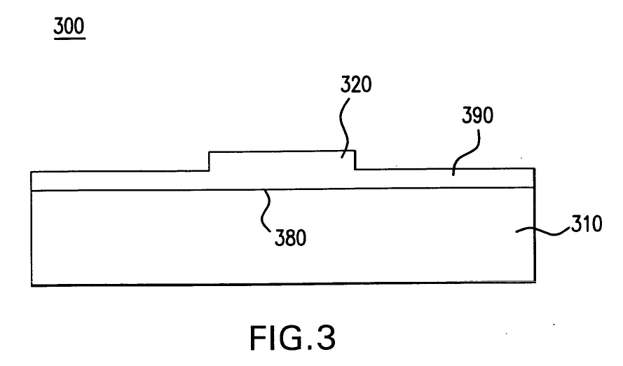

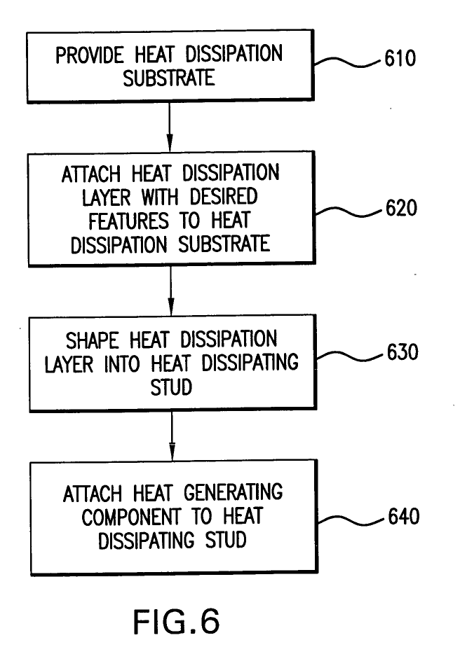

FIG. 3 shows a heat-dissipating device according to a third embodiment of the present invention. In FIG. 3, a heat-dissipating substrate 310 is provided of a predetermined size and material, metal, alloy or composite for precise requirements of a particular heat-dissipating application. As shown in FIG. 6, after the substrate is selected 610, a layer 390 of a material selected to form a heat-dissipating stud 320 is attached 620 by any known attachment means, such as brazing, soldering, adhesive bonding, diffusion bonding, vacuum hot pressing, etc. After the layer 390 is attached, a stud 320 of a predetermined size for mating with the device to be cooled is formed 630 by machining, laser cutting, chemical etching, or other known process at a predetermined location 330 on a top surface of layer 390. After the heat-dissipating stud 320 is formed in layer 390, the device to be cooled may be attached 640. The heat-dissipating stud is shaped to fit the electronic device to be cooled.

An application of the above-described heat-dissipating assembly elements in an integrated circuit device-cooling situation will now be described with reference to FIGS. 7 and 8. The integrated circuit device 741 comprises an electrical interconnect support structure 742 made of one or more layers of relatively inexpensive dielectric material such as polyamide or other polymer dielectrics, or epoxy materials having a relatively high CTE. The support structure 742 supports a heat-dissipating substrate 743 chosen for application specific qualities as described previously with respect to substrates 110, 210, and 310 and FIGS. 1-8.

A heat-dissipating stud 745 rising from the upper surface 746 of the heat-dissipating substrate 743 supports a microchip or die 744. The heat-dissipating stud 745 is manufactured separately from the heat-dissipating substrate 743 and then attached to the heat-dissipating substrate 743 by brazing, resistance welding, ultrasonic welding, pressing, i.e., cold fusion under high pressure, soldering, adhesive bonding, press fit, screws, rivets, diffusion bonding, or with use of an adhesion layer 751 of thermally conductive adhesive material or other thin adhesion material of a thickness to be determined by thermal performance requirements. A series of wire-bonds 747 connect contact points on the die 744 to metalization 748 patterned onto the surface 749 or within the body of support structure 742. The metalization connects to a plurality of leads 750 extending outward from the integrated circuit device 741. Heat-dissipating substrate 743 may be sized/shaped such that it may form part of the encapsulation structure, not shown.

It should be noted that in order to reduce heat-dissipating expenses in integrated circuit devices, the heat-dissipating substrate 743 may be selected from various generic materials, sizes and shapes, selected for it heat-dissipating qualities, low mass, environmental conditions resistance, price, etc. In order to distribute and reduce the mechanical stress at the junction of the various components of the device, the materials used for the support structure 742 are selected to have intermediate CTE's between the heat-dissipating substrate 743 and the metalization 748. The heat-dissipating stud 745 is selected from various materials to provide an intermediate CTE between the heat-dissipating substrate 743 and the integrated circuit die 744, along with other desired application specific features such as customizing of CTE matching to die, sizing, environment resistance, price, mass, etc.

The present invention may permit an end user to precisely select various features of a heat sink device to a particular application. The main body of the heat sink, or the substrate, may be of a generic size, shape and material to optimize selected features of the heat sink, such as thermal conductivity, low mass, inexpensive material, inexpensive manufacturing processes, environmental resistance, bondability, etc. While the interface surface, or slug, may be selected of a material, size and shape or made customized to the particular application, in order to optimize selected features, such as improved CTE matching with the device to be cooled, bondability, machinability to precise tolerances, etc.

It should be noted that the application specific shape of the heat-dissipating stud might be formed before or after it is attached to the heat-dissipating substrate. Also, the heat-dissipating stud may be attached to the device to be cooled before or after it is attached to the heat-dissipating substrate. Also, although FIGS. 7-8 illustrate an integrated circuit device 744 being cooled, the present invention is just as applicable to printed circuit boards, multi-chip modules, prepackaged devices, etc. without deviating from the basic concepts of the present invention.

Although this preferred embodiment of the present invention has been disclosed for illustrative purposes, those skilled in the art will appreciate that various modifications, additions and substitutions are possible, without departing from the scope of the invention, resulting in equivalent embodiments that remain within the scope of the appended claims. For example, the generic heat-dissipating substrate may also be a heat-dissipating substrate with fins or other common heat-dissipating physical features.

What is claimed is:

1. An application specific heat sink device for dissipating heat from an electronic component, the application specific heat sink device comprising:
a heat-dissipating substrate selected for one or more of the following properties: size, shape, mass, cost, thermal conductivity, environmental resistance; and
a heat-dissipating stud selected for its CTE and machinability properties, wherein the heat-dissipating stud is attached to the heat-dissipating substrate such that the electronic component may be attached to the heat-dissipating stud.

2. The application specific heat sink device in accordance with claim 1, wherein the heat-dissipating substrate comprises Aluminum Silicon Carbide.

3. The application specific heat sink device in accordance with claim 1, wherein the heat-dissipating substrate comprises a carbon-metal alloy.

4. The application specific heat sink device in accordance with claim 1, wherein the heat-dissipating substrate comprises a ceramic.

5. The application specific heat sink device in accordance with claim 1, wherein the heat-dissipating substrate includes fins.

6. The application specific heat sink device in accordance with claim 1, wherein the heat-dissipating stud comprises a material with a CTE relatively close to the CTE of the electronic component to be cooled.

7. The application specific heat sink device in accordance with claim 1, wherein the heat-dissipating stud comprises a material with a CTE relatively intermediate between the CTE of the electronic component to be cooled and the heat-dissipating substrate.

8. The application specific heat sink device in accordance with claim 1, wherein the heat-dissipating stud comprises a metal, a metal alloy or combinations thereof.

9. An application specific heat sink device in accordance with claim 1, wherein the heat-dissipating substrate comprises a cavity on a first surface, wherein the heat-dissipating stud is attached to the heat-dissipating substrate within the cavity on the first surface of the heat-dissipating substrate, wherein the cavity provides an alignment means.

10. An application specific heat sink device in accordance with claim 1, wherein the heat-dissipating stud is formed by forming a layer of application specifically selected material to a top surface of the heat-dissipating substrate and then forming the heat-dissipating stud from the application specifically selected material.

11. An application specific heat sink device in accordance with claim 10, wherein the heat-dissipating stud is formed by machining, laser cutting or chemical etching the heat-dissipating stud from the layer of application specifically selected material.

12. A method for manufacturing an application specific heat sink device, comprising:
selecting a heat-dissipating substrate;
forming a heat-dissipating stud, wherein the heat-dissipating stud is shaped and sized to mate with an electronic device to be cooled; and
attaching the heat-dissipating stud to the substrate.

13. The method in accordance with claim 12, wherein the heat-dissipating substrate comprises Aluminum Silicon Carbide.

14. The method in accordance with claim 12, wherein the heat-dissipating stud comprises a material selected to have a relatively close CTE with the electronic device to be cooled.

15. The method in accordance with claim 12, wherein the heat-dissipating stud comprises a material selected to have an intermediate CTE between the heat-dissipating substrate and a device to be cooled.

16. The method in accordance with claim 12, wherein the heat-dissipating substrate is selected for one or more of the following qualities, thermal conductivity, environmental resistance, low mass, inexpensive price, or bondability.

17. The method in accordance with claim 12, further comprising the step of forming a cavity in a top surface of the heat-dissipating substrate; wherein the heat-dissipating stud is attached within the cavity formed on the heat-dissipating substrate.

18. The method in accordance with claim 12, wherein the heat-dissipating substrate includes fins.
